(19) United States
(12) Patent Application Publication
(10) Pub. No.: US 2018/0057929 A1
(43) Pub. Date: Mar. 1, 2018

(54) Method of Depositing Aluminum Oxide Film, Method of Forming the Same, and Sputtering Apparatus

(71) Applicant: ULVAC, INC., Kanagawa (JP)

(72) Inventors: Yuusuke Miyaguchi, Kanagawa (JP); Shinya Nakamura, Kanagawa (JP); Yoshihiro Ikeda, Kanagawa (JP); Koukou Suu, Kanagawa (JP)

(73) Assignee: ULVAC, INC., Kanagawa (JP)

(21) Appl. No.: 15/555,316

(22) PCT Filed: Feb. 16, 2016
(86) PCT No.: PCT/JP2016/000786

§ 371 Date: Sep. 1, 2017

(30) Foreign Application Priority Data
Mar. 10, 2015 (JP) 2015-046947

(51) Int. Cl. C23C 14/58; C23C 14/08; C23C 14/35; H01J 37/34; H01L 21/02

(52) U.S. Cl. CPC C23C 14/5806; C23C 14/081; C23C 14/35; H01L 21/32; H01L 21/02178; H01L 21/02266; H01J 37/3405

(57) ABSTRACT

There are provided a method of depositing an aluminum oxide film, a method of forming the same, and a sputtering apparatus, which are capable of depositing an aluminum oxide film that can be crystallized at a low-temperature annealing process. In the method of depositing an aluminum oxide film according to this invention, a target made of aluminum oxide and a substrate W to be processed are disposed inside a vacuum chamber, a rare gas is introduced into the vacuum chamber, and HF power is applied to the target to thereby deposit by sputtering the aluminum oxide film on the surface of the substrate, the pressure in the vacuum chamber during film deposition is set to a range of 1.6 through 2.1 Pa.

### TECHNICAL FIELD

The present invention relates to a method of depositing an aluminum oxide film, a method of forming the same, and a sputtering apparatus.

### BACKGROUND ART

Recently, much attention is being paid to a 3D (three-dimensional)-NAND flush memory that is a mass storage semiconductor memory. The 3D-NAND flush memory is manufactured by laminating multilayer memory cells, and the steps of manufacturing the same include a step of depositing an aluminum oxide film, an etching step in which the aluminum oxide film thus deposited is used as a hard mask, and the like steps. As a method of depositing the aluminum oxide film for this kind of use, there is known an ALD (atomic layer deposition) method (see, for example, non-patent document 1). This method, however, has a problem in that the film deposition speed is low. As a solution, it is being studied to deposit the aluminum oxide film by using a sputtering method which is high in productivity.

It is generally known that, when the aluminum oxide film is deposited by the sputtering method, the film thus deposited becomes amorphous. The amorphous aluminum oxide film has a low etching resistance and does not serve the function as a hard mask as it is. Therefore, by carrying out an annealing process to the amorphous aluminum oxide film prior to the etching step to thereby crystallize the aluminum oxide film, etching resistance is enhanced (see, for example, patent document 1).

By the way, since the number of steps of manufacturing the 3D-NAND flush memory is larger than that of a conventional 2D (two dimensional) flush memory, it is desired from the viewpoint of reducing the heat history to lower the temperature of crystallizing the aluminum oxide film (annealing temperature) below 850° C., preferably below 800° C.

However, in case the aluminum oxide film is deposited by sputtering method, it is normal practice to deposit the film at room temperature at which the substrate is not positively heated. If the temperature of annealing process to be carried out on the aluminum oxide film that has been deposited at room temperature in the manner as descried above is lowered, there was a problem in that the aluminum oxide film is not crystallized.

### PRIOR ART DOCUMENTS

### Patent Documents

Patent Document 1: JP-2003-168679 A

### Non-Patent Documents

Non-patent document 1: Sun Jin YUN and 3 others, “Large-Area Atomic Layer Deposition and Characterization of Al₂O₃ film Grown Using AlCl₃ and H₂O”, Journal of the Korean Society, Vol. 33, November 1998, pp. S170-S174

### SUMMARY OF THE INVENTION

### Problems that the Invention is to Solve

This invention has a problem of providing a method of depositing an aluminum oxide film, a method of forming the same, and a sputtering apparatus, in all of which the aluminum oxide film can be crystallized even in a low-temperature annealing process.

### Means of Solving the Problems

In order to solve the above problems, a method of depositing an aluminum oxide film according to this invention in which: a target made of aluminum oxide and a substrate to be processed are disposed inside a vacuum chamber; a rare gas is introduced into the vacuum chamber; and RF (radio frequency) power is applied to the target in order to deposit by sputtering an aluminum oxide film on a surface of the substrate is characterized in that the pressure in the vacuum chamber during film deposition is set to a range of 1.6 through 2.1 Pa.

According to this invention, by setting the pressure in the vacuum chamber during film deposition to a range of 1.6 through 2.1 Pa, even if the temperature of annealing process that is carried out after film deposition of amorphous aluminum oxide film is lowered, the aluminum oxide film can be crystallized. In the experiments that will be described hereinafter, it has been confirmed that the aluminum oxide film could be crystallized even if the temperature of annealing process, to be carried out after deposition of amorphous aluminum oxide film, was set to 800° C. through 850° C. When the pressure in the vacuum chamber is below 1.6 Pa, there is a case in which the etching resistance lowers. On the other hand, when the pressure in the vacuum chamber exceeds 2.1 Pa, there is a case in which the productivity lowers or the in-plane film thickness distribution of the substrate becomes deteriorated.

In this invention, preferably the temperature of the substrate during film deposition is set to a range of 450° C. through 550° C. According to this arrangement, the atoms that constitute the deposited amorphous aluminum oxide film tend to become more easily movable when annealing process is carried out thereon, as compared with the atoms that constitute the aluminum oxide film deposited at room temperature. Therefore, even if the temperature is lowered of annealing process to be carried out after the amorphous aluminum oxide film is deposited by using the method of depositing an aluminum film according to this invention, the aluminum oxide film can be crystallized. In the experiments to be described hereinafter, it has been confirmed that the aluminum oxide film can be crystallized even if the temperature of annealing process is set to 800° C.

Further, according to this invention, preferably the RF power to be applied to the target is set to a range of 1 kW through 4 kW. If the RF power goes outside this range, there is a case where the productivity or etching resistance lowers.

According to the method of forming an aluminum oxide film of this invention, by depositing an aluminum oxide film using the above-mentioned method of depositing the aluminum oxide film, and by annealing the deposited aluminum oxide film at 800° C. through 850° C. the aluminum oxide film can be crystallized. In this case, if the temperature of the substrate during film deposition is set to a range of 450° C. through 550° C., the aluminum oxide film can advantageously be crystallized by annealing at 800° C.

A sputtering apparatus for carrying into effect the method of depositing an aluminum oxide film according to this invention comprises: a vacuum chamber in which a target made of aluminum oxide is disposed; a stage which holds a substrate to be processed, in a manner to lie opposite to the target in the vacuum chamber; a sputtering power supply which applies HF power to the target; and a gas introduction means which introduces a rare gas into the vacuum chamber, characterized in that the sputtering apparatus further comprises a heating means which heats the substrate during film deposition to a temperature within a range of 450° C. through 550° C.

### BRIEF DESCRIPTION OF THE DRAWINGS

FIG. 1 is a schematic view explaining the constitution of the sputtering apparatus according to an embodiment of this invention.

FIG. 2 is a graph showing the results of experiments to confirm the effects of this invention.

FIG. 3 is a graph showing the results of experiments to confirm the effects of this invention.

### MODES FOR CARRYING OUT THE INVENTION

With reference to the drawings, a description will now be made of a method of depositing an aluminum oxide film and of a sputtering apparatus according to an embodiment of this invention, based on an example in which an aluminum oxide film is deposited by sputtering method on a surface of a substrate W.

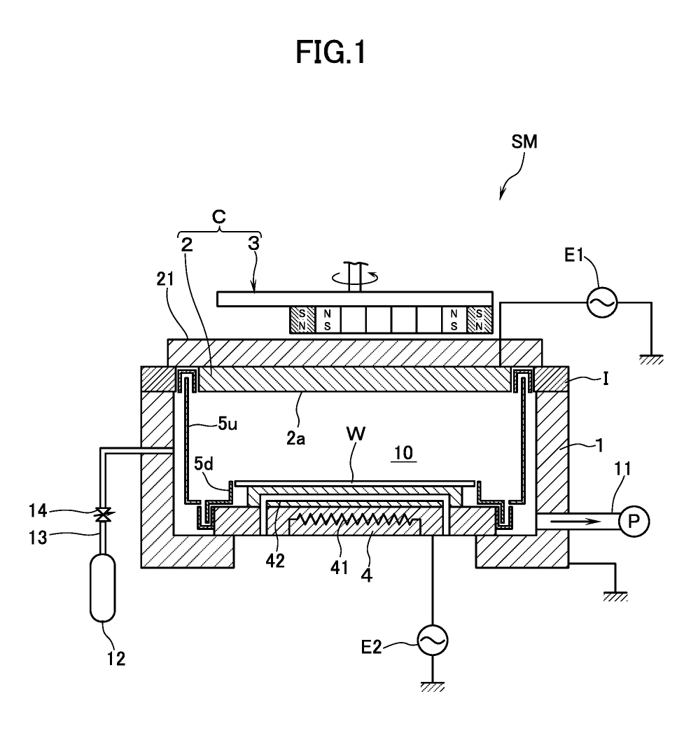

With reference to FIG. 1, the sputtering apparatus SM according to this embodiment is provided with a vacuum chamber 1 which defines a processing chamber 10. To a side wall of the vacuum chamber 1 there is connected a vacuum pump P via an exhaust pipe 11. It is thus so arranged that the inside of the vacuum chamber 1 can be evacuated to a predetermined pressure (e.g., 1×10⁻⁵ Pa). Further, the side wall of the vacuum chamber 1 has connected thereto a gas introduction pipe 13 from a gas source 12. It is so arranged that a rare gas such as argon whose flow rate is controlled by a mass flow controller 14 can be introduced into the vacuum chamber 1. The gas source 12, the gas introduction pipe 13, and the mass flow controller 14 constitute the “gas introduction means” of this invention. In the following description, the terms denoting the direction such as “top or upper”, “bottom or lower”, and the like will be explained with FIG. 1 serving as a standard.

On an upper portion of the vacuum chamber 1 there is provided a cathode unit C. The cathode unit C is constituted by a target 2, and a magnet unit 3 which is disposed above the target 2. The target 2 is made of an aluminum oxide and is formed by a known method into a circular shape or a rectangular shape as seen in plan view (i.e., as seen from top downward). The target 2 is bonded, via a bonding material such as indium, zinc and the like (not illustrated), to a copper backing plate 21 which serves to cool the target 2 during film deposition. In this state, the target 2 is mounted on an upper portion of the vacuum chamber 1 through an insulating plate I in a posture in which a sputtering surface 2a of the target 2 faces downward. The target 2 has connected thereto an output of a RF power supply which is a sputtering power source E1. During sputtering, RF power, e.g., of 13.56 MHz is applied to the target 2 by an amount of 1 kW through 4 kW. The magnet unit 3 has a known construction in which a magnetic field is generated in a space below the sputtering surface 2a, the electrons and the like that are electrolytically dissociated below the sputtering surface 2a at the time of sputtering are captured. In this manner, the sputtered particles scattered from the target 2 are efficiently ionized. Therefore, detailed description thereof is omitted here.

At the bottom portion of the vacuum chamber 1 there is disposed a stage 4 which holds the substrate W at a position to lie opposite to the target 2. The stage 4 is provided with an electrode for an electrostatic chuck (not illustrated). It is thus so arranged that, by applying chucking voltage to this electrode, the substrate W can be held in an aligned position. The stage 4 has built therein a heating means 41 such as a resistance heating type of heater and the like. It is thus so arranged that the temperature of the substrate W during film deposition can be heated and held in a range of 450° C. through 550° C. Together with this arrangement, the stage 4 has formed therein a passage 42 for circulating a coolant such as cooling water and the like so that the substrate W held by the stage 4 can be cooled.

Inside the vacuum chamber 1 there are provided a pair of upper and lower deposition prevention plates 5u, 5d made of metal such as stainless steel and the like. During film deposition by sputtering, sputtered particles are prevented from getting adhered to the internal wall surfaces of the vacuum chamber 1. The above-mentioned sputtering apparatus SM has a control means (not illustrated) provided with a known microcomputer, sequencer, and the like. It is thus so arranged that the control means carries out an overall control over the operation of the heating means 41, the operation of the sputtering power source E1, the operation of the mass flow controller 14, the operation of the vacuum pump P, and the like. Description will now be made of a method of deposition using the above-mentioned sputtering apparatus SM.

First, the inside of the vacuum chamber 1 (processing chamber 1a) is evacuated to a predetermined vacuum degree, and a substrate W is transferred into the vacuum chamber 1 by means of a transfer robot (not illustrated), and the substrate W is thus held in position on the stage 4. Then, the heating means 41 is operated to heat the substrate W to 450° C. through 550° C. When the substrate W has reached a predetermined temperature (e.g., 450° C.), argon gas as a sputtering gas is introduced into the vacuum chamber 1 at a flow rate of 175 through 250 sccm (the pressure at this time is 1.6 through 2.1 Pa). By applying HF power from the sputtering power supply E1 to the target 2, plasma atmosphere is formed inside the processing chamber 10. According to this arrangement, the target 2 gets sputtered and the sputtered particles generated by sputtering will be scattered for adhesion to the surface of the substrate W and accumulated to deposit an amorphous aluminum oxide film.

Here, it is preferable to set the HF power to be applied to the target 2 to a range of, e.g., 13.56 MHz at 1 kW through 4 kW. If the HF power is outside this range, there is a case where the productivity or the etching resistance lowers. Further, when the pressure in the vacuum chamber during film deposition is below 1.6 Pa, there is a case in which the etching resistance lowers and, when it exceeds 2.1 Pa, there is a case in which the productivity is lowered or the in-plane film thickness distribution of the substrate will be deteriorated.

According to the above-described embodiment, since the substrate W is heated to 450° C. through 550° C. during film deposition by sputtering, the atoms constituting the deposited amorphous aluminum oxide film become more easily movable when subjected to annealing process as compared with the atoms constituting the aluminum oxide film deposited at room temperature. Therefore, even if the temperature of annealing process to be carried out after film deposition by using the method of deposition according to this embodiment, is lowered to about 800° C., the aluminum oxide film can be crystallized.

In addition, by setting the pressure in the vacuum chamber to a range of 1.6 through 2.1 Pa during film deposition by sputtering, the aluminum oxide film can be crystallized even if the temperature of annealing process to be carried out after film deposition by using the method of deposition according to this embodiment, is lowered to 800 through 850° C.

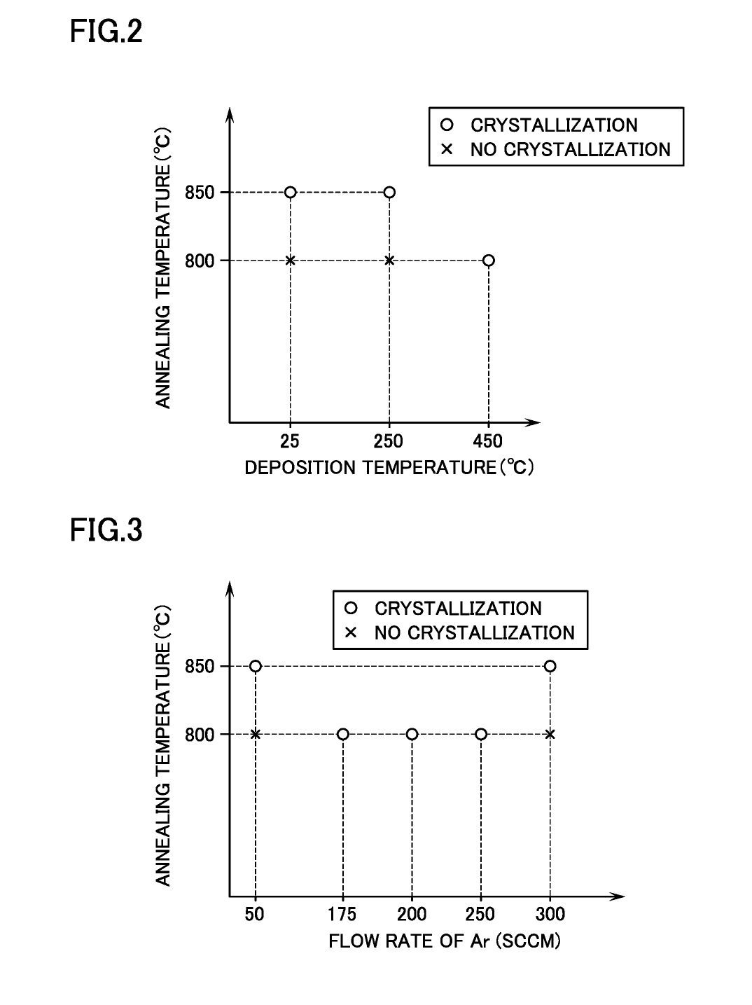

Subsequently, in order to confirm the effects of this invention, the following experiments were carried out using the above-mentioned sputtering apparatus SM. In these experiments, a substrate W was selected to be a silicon wafer of φ300 mm (in diameter). After setting in position the substrate Won the stage 4 in the vacuum chamber 1 in which a target 2 made of aluminum oxide was assembled, the heating means 41 was operated to heat the substrate W to a temperature of 450° C. When the temperature of the substrate W reached 450° C., argon gas was introduced into the vacuum chamber 1 at a flow rate of 200 sccm (the pressure in the vacuum chamber 1 at this time was 1.8 Pa). Then, by applying RF power of 13.56 MHz at 4 kW from the sputtering power source E1 to the target 2, plasma atmosphere was formed inside the processing chamber 10, thereby depositing an amorphous aluminum oxide film on the surface of the substrate W. The substrate W on which the amorphous aluminum oxide film was deposited was taken out of the sputtering SM, and was subjected to annealing process relative to the amorphous aluminum oxide film at a temperature of 800° C. by using a lamp annealing apparatus (manufactured by ULVAC-RIKO, type “RTA-12000”). The aluminum oxide film after the annealing process was defined as “Invention Product 1.” As a result of X-ray diffraction analysis of the Invention Product 1, crystallization of the film was confirmed (see FIG. 2).

In addition, except for the point that the substrate W temperature during film deposition was set to 250° C., an amorphous aluminum oxide film was deposited in the same method as in the above-mentioned Invention Product 1. As shown in FIG. 2, crystallization did not take place even by subjecting the aluminum oxide film whose deposition temperature was 250° C. to annealing process at 800° C., but crystallization has been confirmed when subjected to annealing process at 850° C. Similarly, when the heating means 41 was not operated during the film deposition but by setting the deposition temperature to 25° C. (room temperature), crystallization did neither take place even by subjecting the film to annealing process at 800° C. It has then been confirmed that crystallization took place when subjected to annealing process at 850° C.

Further, except for the points that setting was made for the flow rates of argon at 50 sccm, 175 sccm, 200 sccm (the above-mentioned Invention Product), 250 sccm, 300 sccm (at this time the pressures in the vacuum chamber 1 were 0.2 Pa, 1.6 Pa, 1.8 Pa, 2.1 Pa, 2.3 Pa), amorphous aluminum oxide films were respectively deposited in a similar method as in the above-mentioned Invention Product 1. As shown in FIG. 3, when film was deposited by setting the flow rate of argon to 175 sccm, 200 sccm, 250 sccm, crystallization has been confirmed, in the same manner as in the Invention Product 1, by annealing process at 800° C. On the other hand, when film was deposited by setting the flow rate of argon to 50 sccm, 300 sccm, it has been confirmed that crystallization does not take place by annealing process at 800° C., but that crystallization takes place by annealing process at 850° C. According to the above experiments, it has been found that lowering in temperature of the annealing process can be attained if the flow rate of argon is set to 175 through 250 sccm, namely, if the pressure in the vacuum chamber 1 during film deposition is set to 1.6 through 2.1 Pa.

In addition, except for the point that the RF power to be applied to the target 2 was set to 1 kW, in a similar manner as in the above-mentioned Invention Product 1, amorphous aluminum oxide films were respectively deposited, annealing process was carried out at 800° C. to thereby crystallize the film, and the crystallized product was defined as Invention Product 2. Then, the Invention Product 1 and the Invention Product 2 were subjected to wet etching with etching liquid of H₂O: HF=500:1 and the etching rates were measured. The etching rates of the Invention Product 1 and the Invention Product 2 were confirmed to be 135 Å/min, 193 Å/min, respectively. According to these results, it has been found that, if the HF power was set to a value below 1 kW, the etching rates became high and the etching resistance lowered.

Description has been made of the embodiments of this invention. However, this invention shall not be limited to the above. For example, as shown in FIG. 1, by connecting an output of another HF power source E2 to the stage 4 and by applying a predetermined bias power to the stage 4 during film deposition, the constituting atoms of the aluminum oxide film can be made easier to move at the time of annealing process. In this case, as the bias power, it is preferable to apply HF power of 13.56 MHz at 13 through 45 W.

### EXPLANATION OF REFERENCE CHARACTERS

SM sputtering apparatus

W substrate

1 vacuum chamber

2 target

4 stage

41 heating means

E1 sputtering power source

12, 13, 14 gas introduction means

1. A method of depositing an aluminum oxide film comprising:
disposing inside a vacuum chamber a target made of aluminum oxide and a substrate to be processed;
introducing a rare gas into the vacuum chamber; and
applying RF power to the target in order to deposit by sputtering an aluminum oxide film on a surface of the substrate,
characterized in that a pressure in the vacuum chamber during film deposition is set to a range of 1.6 through 2.1 Pa; and
that a temperature of the substrate during film deposition is set to a range of 450° C. through 550° C.

2. (canceled)

3. The method of depositing an aluminum oxide film according to claim 1, wherein the RF power to be applied to the target is set to a range of 1 kW through 4 kW.

4. A method of forming an aluminum oxide film comprising:
depositing an aluminum oxide film by using the method of depositing the aluminum oxide film according to claim 1; and
annealing the deposited aluminum oxide film at 800° C. through 850° C. in order to crystallize the aluminum oxide film.

5. (canceled)

6. A sputtering apparatus for carrying into effect the method of depositing an aluminum oxide film according to claim 1, the apparatus comprising:
a vacuum chamber in which a target made of aluminum oxide is disposed;
a stage which holds a substrate to be processed, in a manner to lie opposite to the target in the vacuum chamber;
a sputtering power supply which applies HF power to the target; and
a gas introduction means which introduces a rare gas into the vacuum chamber,
wherein the sputtering apparatus further comprises a heating means which heats the substrate during film deposition to a temperature within a range of 450° C. through 550° C.
